(19) United States
(12) Patent Application Publication
(10) Pub. No.: US 2007/0012245 A1
(43) Pub. Date: Jan. 18, 2007

(54) SEMICONDUCTOR MANUFACTURING APPARATUS AND COOLANT CIRCULATING METHOD USING THE SAME

(75) Inventor: Min-Soo PARK, Gyeonggi-do, (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do, (KR)

(21) Appl. No.: 11/457,759

(22) Filed: Jul. 14, 2006

(30) Foreign Application Priority Data
Jul. 14, 2005 (KR) 2005-0063866

(51) Int. Cl. H01L 21/44; B05C 11/02

(52) U.S. Cl. 118/117; 438/660

(57) ABSTRACT

A semiconductor manufacturing apparatus and a coolant circulating method are provided. The semiconductor manufacturing apparatus includes: at least two chamber bodies; a chamber lid constituting common tops of at least the two chamber bodies; first and second manifolds supplying a process gas to at least the two chamber bodies, respectively; a third manifold supplying a cleaning gas to at least the two chamber bodies; and first and second coolant lines supplying and retrieving a coolant to the third manifold.

### CROSS REFERENCE TO RELATED APPLICATIONS

This application claims priority from Korean Patent Application No. 2005-63866, filed on Jul. 14, 2005, the content of which is hereby incorporated by reference in its entirety for all purposes.

### BACKGROUND

1. Field of the Invention

The present invention relates to a semiconductor manufacturing apparatus and a coolant circulating method using the same, and more particularly, to a semiconductor manufacturing apparatus with an improved coolant line of a chamber lid in a semiconductor manufacturing equipment, and a coolant circulating method using the same.

2. Description of the Related Art

Generally, various kinds of semiconductor equipments have been used to manufacture a semiconductor device. One of them is a chemical vapor deposition (CVD) equipment. An example of the CVD equipment, as illustrated in FIG. 1, is a model called “PRODUCER SACVD” of an AMAT company. This semiconductor equipment 10 includes a chamber in which actual process is performed and a top of the chamber includes a chamber lid 11. A coolant is supplied and circulated in the chamber lid to maintain a predetermined temperature. The coolant is circulated between the chamber lid 11 and a heat exchanger (not shown). The coolant is supplied and circulated inside the chamber lid 11 through coolant lines 13a, 13b and 13c connected to manifolds 12a and 12b on the chamber lid 11. The manifolds 12a and 12b are connected to gas boxes 14a and 14b. Moreover, since a remote plasma source (RPS) manifold 15 is installed on the chamber lid 11, a cleaning gas for cleaning the inside of the chamber is supplied into the chamber.

A specific coolant circulation is as follows. First, a coolant is flowed into the manifold 12a from the heat exchanger through the coolant line 13a (\textcircled{1}), and the flowed coolant is supplied into the chamber lid 11 (\textcircled{2})). The coolant supplied and circulated in the chamber lid 11 comes out to the manifold 12a (\textcircled{3}), and enters the manifold 12b through the coolant line 13b (\textcircled{4}). The coolant flowed into the manifold 12b is supplied to the inside of the chamber lid 11 (\textcircled{5}), and also the coolant supplied to the inside of the chamber lid 11 is circulated and comes out again to the manifold 12b from the chamber lid 11 (\textcircled{6}). The coolant coming out to the manifold 12b is discharged to the outside of the chamber lid 11 through the coolant line 13c (\textcircled{7}) and then enters the heat exchanger.

However, the coolant lines 13a to 13c are repeatedly disconnected and connected in a conventional way, which are connected to inner manifolds 12a and 12b in a supply part of a process gas during a preventative maintenance (PM) or a breakdown maintenance (BM) for the semiconductor manufacturing apparatus 10. A connection part is worn out according to repeated disconnection and connection of the coolant lines 13a to 13c, and furthermore coolant leakage occurs. Therefore, a stable operation becomes problematic in the chamber, and consequently a yield decreases.

### SUMMARY

The present invention provides a semiconductor manufacturing apparatus with an improved coolant line structure to reduce a stop loss of equipments and a coolant circulating method using the same.

To achieve these objects and other advantages and in accordance with the purpose of the invention, there is provided a semiconductor manufacturing apparatus with an improved coolant line structure and also designing a connection part to be semi-permanent and a coolant circulating method using the same.

Embodiments of the present invention provide a semiconductor manufacturing apparatus including: at least two chamber bodies; a chamber lid constituting common tops of at least the two chamber bodies; first and second manifolds supplying a process gas to at least the two chamber bodies, respectively; a third manifold supplying a cleaning gas to at least the two chamber bodies; and first and second coolant lines supplying and retrieving a coolant to the third manifold.

In some embodiments, the semiconductor manufacturing apparatus further includes a fourth manifold providing a flow path of the coolant by connecting the third manifold to the first manifold; and a fifth manifold providing a flow path of the coolant by connecting the third manifold to the second manifold.

In further embodiments, at least one of the first and second coolant lines is semi-permanently connected to the third manifold.

In other embodiments, the coolant is supplied to the third manifold through the first coolant line and retrieved from the third manifold through the second coolant line.

In other embodiments, the semiconductor manufacturing apparatus further includes a coolant supplier supplying the coolant to the first coolant line by connecting to an end of the first coolant line. The first coolant line is semi-permanently connected to the coolant supplier.

In other embodiments, the semiconductor manufacturing apparatus further includes a coolant retriever retrieving the coolant from the second coolant line by connecting to an end of the second coolant line.

In other embodiments, the first manifold supplies the coolant supplied from the third manifold to one among at least the two chamber bodies.

In other embodiments, the second manifold supplies the coolant drained from the one among at least the two chamber bodies to the third manifold.

In other embodiments, the first coolant line is installed to circumvent a top of the first manifold. The second coolant line is installed to circumvent a top of the second manifold.

In further embodiments of the present invention, a semiconductor manufacturing apparatus includes: a plurality of chamber bodies; a chamber lid constituting common tops of the plurality of chamber bodies; a plurality of inner manifolds supplying a process gas to the plurality of chamber bodies; an RPS (remote plasma source) manifold supplying a plasma source gas to the plurality of chamber bodies; a coolant supplying line supplying a coolant to the RPS manifold and a coolant retrieving line retrieving the coolant from the RPS manifold; a plurality of Teflon manifolds delivering the coolant, which are between the RPS manifold and the plurality of manifolds; and a coolant retriever retrieving the coolant from a coolant supplier supplying the coolant to the coolant supplying line and the coolant retrieving line.

In some embodiments, the coolant supplying line is semi-permanently connected to the RPS manifold. The coolant supplying line is semi-permanently connected to the coolant supplier.

In further embodiments, the coolant retrieving line is semi-permanently connected to the RPS manifold. The coolant retrieving line is semi-permanently connected to the coolant retriever.

In other embodiments, the coolant supplying line and the coolant retrieving line are installed to circumvent tops of the plurality of inner manifolds.

In other embodiments of the present invention, there is provided a coolant circulating method using a semiconductor apparatus including at least two chamber bodies, a chamber lid constituting common tops of at least the two chamber bodies, first and second manifolds supplying a process gas to at least the two chamber bodies, respectively, a third manifold supplying a cleaning gas to at least the two chamber bodies, and first and second coolant lines supplying and retrieving a coolant to the third manifold. The coolant circulating method includes: supplying the coolant to the third manifold through the first coolant line; flowing the coolant to the first manifold from the third manifold; flowing the coolant to one among at least the two chamber bodies from the first manifold; draining the coolant to the third manifold from the one among at least the two chamber bodies; flowing the coolant to the second manifold from the third manifold; flowing the coolant to another one among at least the two chamber bodies from the second manifold; draining the coolant to the third manifold from another one among at least the two chamber bodies; and retrieving the coolant from the third manifold through the second coolant line.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a perspective view of a conventional semiconductor manufacturing apparatus;

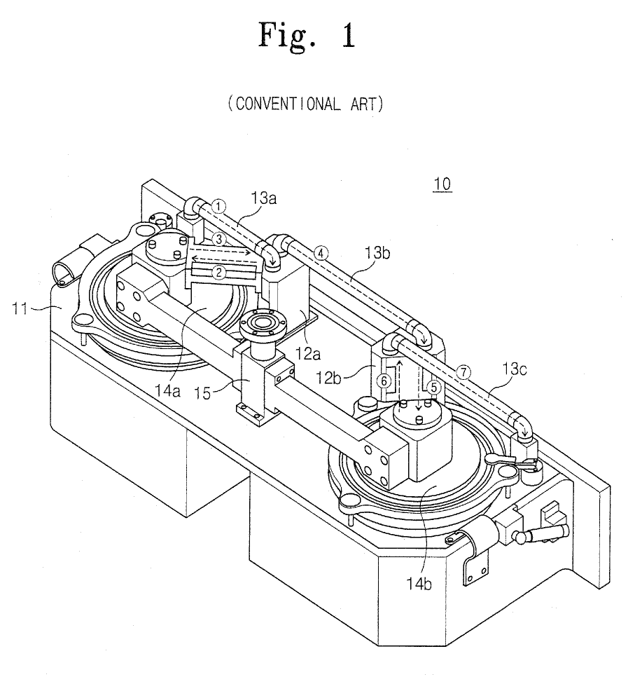

FIG. 2 is a perspective view of a semiconductor manufacturing apparatus according to an embodiment of the present invention;

FIG. 3 is a perspective view of a coolant line in a semiconductor manufacturing apparatus according to an embodiment of the present invention; and

FIG. 4 is a perspective view of a semiconductor manufacturing apparatus with a modified coolant line structure according to an embodiment of the present invention.

### DETAILED DESCRIPTION

Reference will now be made in detail to the preferred embodiments of the present invention, examples of which are illustrated in the accompanying drawings. However, the present invention is not limited to the embodiments illustrated herein after, and the embodiments herein are rather introduced to provide easy and complete understanding of the scope and spirit of the present invention. In any possible case, like reference numerals refer to like or similar elements throughout the drawings.

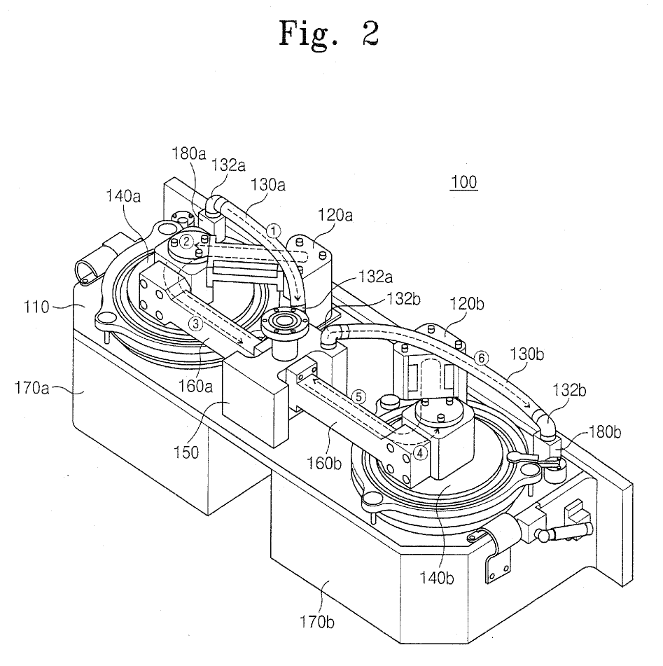

Hereinafter, a semiconductor manufacturing apparatus and a coolant circulating method will now be described in more detail with reference to FIGS. 2 to 4.

Referring to FIG. 2, a semiconductor manufacturing apparatus 100 includes a chamber lid 110 constituting a top of the chamber. The semiconductor manufacturing apparatus 100, for example, is a chemical vapor deposition (CVD) apparatus supplying a predetermined gas to a chamber and depositing a predetermined thin layer on a wafer using a chemical reaction.

Manifolds 120a and 120b, i.e. inner manifolds are installed on a top of the chamber lid 110 to supply gas used in a CVD process to the inside of the chamber. Each of the inner manifolds 120a and 120b has an appropriate structure for a coolant flow as will be described below.

Each of the inner manifolds 120a and 120b is connected to gas boxes 140a and 140b, respectively. The process gas moves through the inner manifolds 120a and 120b and the inside of the gas boxes 140a and 140b. A bottom of the chamber lid 110 includes bodies 170a and 170b constituting a part of the chamber. The bodies 170a and 170b forms, for example, a chamber wall and may include a heater to supply a necessary heat for the CVD process.

In the semiconductor manufacturing apparatus 100, when the CVD process is in progress, a thin layer may be deposited on a diffuser supplying the process gas and a chamber inner wall as well as wafers. The thin layer deposited on an unwanted area becomes particles because a part of the thin layer is separated due to a thermal stress, etc. during the process. Accordingly, a cleaning gas, e.g. NF3 and Ar, is supplied to the chamber and a plasma etching is performed in order to remove the thin layer, which is served as particles deposited on the chamber inner wall and the diffuser, etc. For this, a manifold 150 is installed on the chamber lid 110 to supply the cleaning gas. Additionally, an RPS box (not shown in detail) is installed on a top of the manifold 150. The manifold 150, i.e. the RPS manifold, also serves to support the RPS box.

The RPS manifold 150 and each of the inner manifolds 120a and 120b are connected to each other through the manifolds 160a and 160b, i.e. Teflon manifolds. The Teflon manifolds 160a and 160b have an appropriate structure for a coolant flow as will be described below.

Coolant lines 130a and 130b supplying coolant (for example, cooling water) are installed on the top of the chamber lid 110 to lower a temperature of the chamber or maintain a predetermined temperature. The coolant lines 130a and 130b are divided into the coolant line 130a supplying a coolant to the chamber and the coolant line 130b retrieving the coolant from the chamber. The coolant line 130a supplying the coolant is installed between a coolant supplier 180a and the RPS manifold 150, and the coolant line 130b retrieving the coolant is installed between a coolant retriever 180b and the RPS manifold 150.

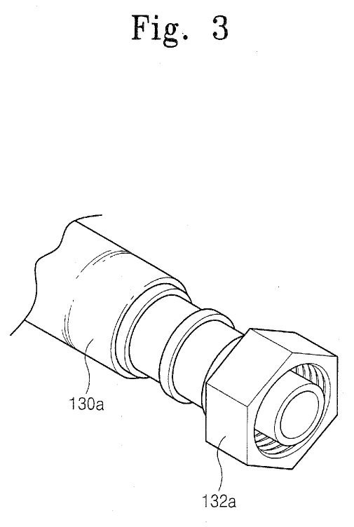

Both ends of the coolant line 130a connect the coolant supplier 180a and the RPS manifold 150 semi-permanently, respectively. A connection structure, as illustrated in FIG. 3, is semi-permanent and/or separable. The coolant line 130b is like the preceding.

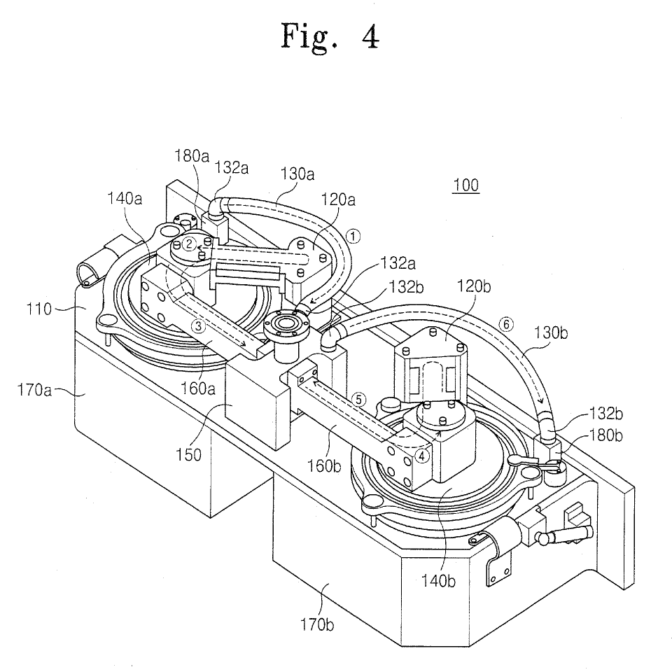

The coolant lines 130a and 130b are installed to cross over the top of the inner manifolds 120a and 120b, but are not thus limited. For example, as illustrated in FIG. 4, each of the coolant lines 130a and 130b may be installed to circumvent (not to cross over) the top of the inner manifolds 120a and 120b. When each of the coolant lines 130a and 130b is installed to circumvent the inner manifolds 120a and 120b, maintenance and repair can be less cumbersome (especially, during disconnection and connection of the inner manifolds 120a and 120b). The coolant lines 130a and 130b can have an arbitrary shape such as a curve shape, a line shape, and a combination of the curve shape and the line shape.

The coolant may be circulated in the semiconductor manufacturing apparatus 1 00 through supplying and retrieving as follows.

A coolant is supplied from the coolant supplier 180a connected to a heat exchanger (not illustrated) and then flowed into the RPS manifold 150 through the coolant line 130a (\textcircled{1})). The coolant flowed into the RPS manifold 150 moves into the inner manifold 120a through the Teflon manifold 160a and then is supplied into the inside of the chamber lid 110 through the gas box 140a by the inner manifold 120a (\textcircled{2}). The coolant supplied to the inside of the chamber lid 110 and circulated in the body 170a comes out to the inner manifold 120a and then comes back to the RPS manifold 150 through the Teflon manifold 160a (\textcircled{3}).

The coolant coming back to the RPS manifold 150 moves along the Teflon manifold 160b and then is supplied to the inside of the chamber lid 110 through the gas box 140b (\textcircled{4}). The coolant supplied to the inside of the chamber lid 110 and circulated in the body 170b comes out to the inner manifold 120b, and then comes back to the RPS manifold 150 through the Teflon manifold 160b (\textcircled{5}). The coolant coming back to the RPS manifold 150 is drained into the coolant retriever 180b through the coolant line 130b, and then retrieved into the heat exchanger (\textcircled{6}). Accordingly, the coolant is supplied to the two chamber bodies, through their associated manifolds, sequentially. For example, the coolant flows through a first chamber and then through a second chamber in sequence. The semiconductor manufacturing apparatus 100 is cooled down or maintained in a predetermined temperature through the coolant circulation.

According to some embodiments, although not illustrated, the coolant is supplied to the chamber bodies, through their associated manifolds, simultaneously. For example, coolant flows through a first chamber and a second chamber at the same time.

As described above, the number of coolant lines is reduced, and also connected to the manifold semi-permanently. Accordingly, when the coolant line is semi-permanently connected to the manifold, abrasion of a connection part can be prevented according to a repeated disconnection and connection of the coolant line, which can occur during maintenance and repair of equipment.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A semiconductor manufacturing apparatus comprising:
at least two chamber bodies;
a chamber lid constituting common tops of at least the two chamber bodies;
first and second manifolds configured to supply a process gas to the at least two chamber bodies;
a third manifold configured to supply a cleaning gas to the at least two chamber bodies; and
first and second coolant lines configured to supply and retrieve a coolant to the third manifold.

2. The semiconductor manufacturing apparatus of claim 1, further comprising:
a fourth manifold configured to provide a first flow path of the coolant by connecting the third manifold to the first manifold; and
a fifth manifold configured to provide a second flow path of the coolant by connecting the third manifold to the second manifold.

3. The semiconductor manufacturing apparatus of claim 1 wherein the coolant is supplied to the third manifold through the first coolant line and retrieved from the third manifold through the second coolant line.

4. The semiconductor manufacturing apparatus of claim 1, further comprising a coolant supplier configured to supply the coolant to the first coolant line by connecting to an end of the first coolant line.

5. The semiconductor manufacturing apparatus of claim 1, further comprising a coolant retriever configured to retrieve the coolant from the second coolant line by connecting to an end of the second coolant line.

6. The semiconductor manufacturing apparatus of claim 1, wherein the first manifold supplies the coolant supplied from the third manifold to one of the at least two chamber bodies.

7. The semiconductor manufacturing apparatus of claim 6, wherein the second manifold supplies the coolant drained from the one of the at least two chamber bodies to the third manifold.

8. The semiconductor manufacturing apparatus of claim 1, wherein the first coolant line is configured to circumvent a top of the first manifold.

9. The semiconductor manufacturing apparatus of claim 1, wherein the second coolant line is configured to circumvent a top of the second manifold.

10. A semiconductor manufacturing apparatus comprising:
a plurality of chamber bodies;
a chamber lid constituting common tops of the plurality of chamber bodies;
a plurality of inner manifolds configured to supply a process gas to the plurality of chamber bodies;
an RPS (remote plasma source) manifold configured to supply a plasma source gas to the plurality of chamber bodies;
a coolant supplying line configured to supply a coolant to the RPS manifold and a coolant retrieving line configured to retrieve the coolant from the RPS manifold;
a plurality of manifolds configured to deliver the coolant, the plurality of manifolds disposed between the RPS manifold and the plurality of inner manifolds; and
a coolant retriever configured to retrieve the coolant from a coolant supplier, the coolant supplier configured to supply the coolant to the coolant supplying line and the coolant retrieving line.

11. The semiconductor manufacturing apparatus of claim 10, wherein the coolant supplying line and the coolant retrieving line are configured to circumvent tops of the plurality of inner manifolds.

12. A coolant circulating method using a semiconductor manufacturing apparatus including at least two chamber bodies, a chamber lid constituting common tops of the at least two chamber bodies, first and second manifolds supplying a process gas to the at least two chamber bodies, a third manifold supplying a cleaning gas to the at least two chamber bodies, and first and second coolant lines supplying and retrieving a coolant to the third manifold, the coolant circulating method comprising:
supplying the coolant to the third manifold through the first coolant line;
flowing the coolant to the first manifold from the third manifold;
flowing the coolant to one of the at least two chamber bodies from the first manifold;
draining the coolant to the third manifold from the one of the at least two chamber bodies;
flowing the coolant to the second manifold from the third manifold;
flowing the coolant to another one of the at least two chamber bodies from the second manifold;
draining the coolant to the third manifold from the another one of the at least two chamber bodies; and
retrieving the coolant from the third manifold through the second coolant line.

13. A coolant circulating method using a semiconductor manufacturing apparatus including at least two chamber bodies, first and second manifolds supplying a process gas to the at least two chamber bodies, a third manifold supplying a cleaning gas to the at least two chamber bodies, and first and second coolant lines supplying and retrieving a coolant to the third manifold, the coolant circulating method comprising:
supplying the coolant to the third manifold through the first coolant line;
flowing the coolant to the first manifold and the second manifold from the third manifold;
flowing the coolant to the at least two chamber bodies from the first and the second manifolds;
draining the coolant to the third manifold from the at least two chamber bodies;
retrieving the coolant from the third manifold through the second coolant line.

14. The method of claim 13, wherein flowing the coolant to the first manifold and the second manifold comprises flowing the coolant simultaneously through the first manifold and the second manifold.

15. The method of claim 13, wherein flowing the coolant to the first manifold and the second manifold comprises flowing the coolant sequentially through the first manifold and the second manifold.
